(19) United States
(12) Patent Application Publication
(10) Pub. No.: US 2006/0199082 A1
(43) Pub. Date: Sep. 7, 2006

(54) MASK REPAIR

(75) Inventors: Philip S. Flanigan, South Burlington, VT (US); Emily E.(Fisch) Gallagher, Burlington, VT (US); Louis M. Kindt, Milton, VT (US); Michael R. Schmidt, Milton, VT (US); David D. Thibault, Colchester, VT (US); Carey W. Thiel, Williston, VT (US)

Correspondence Address: GREENBLUM & BERNSTEIN, P.L.C., 1950 ROLAND CLARK DRIVE, RESTON, VA, 20191, US

(73) Assignee: INTERNATIONAL BUSINESS MACHINES CORPORATION, Armonk, NY (US)

(21) Appl. No.: 10/906,662

(22) Filed: Mar. 1, 2005

(51) Int. Cl. C03C 25/68; C23C 14/32; B44C 1/22; C03C 15/00; C23F 1/00; C23C 14/00; G03F 1/00

(52) U.S. Cl. 430/5; 204/192.3; 216/41; 204/192.33

(57) ABSTRACT

A photomask repair method is provided which has the spatial resolution of a focused energy beam process without the corresponding potential for damage to the photomask pattern and underlying transparent substrate. A photomask defect is repaired by first providing a masking film over the photomask pattern. Next, a high spatial resolution focused energy beam repair technique, such as laser ablation, focused ion beam, or electron beam, is used to remove a portion of the masking film which corresponds to an underlying defect in the photomask pattern. After the defect in the photomask pattern has been exposed and the rest of the non-defective photomask pattern is protected by the masking film, a chemical etching process is used to remove the defect which selectively etches the photomask pattern material without harming the underlying substrate. Once the defect has been removed, the masking film is removed. Additionally, a conductive layer may be included to reduce charge build up on the surface and its negative impact on charged beam placement control.

### FIELD OF THE INVENTION

The invention relates to photomask repair and more particularly to non-destructive high resolution photomask repair.

### BACKGROUND DESCRIPTION

Semiconductor devices are built using a lithographic imaging technique that relies on templates of the desired design. These templates, or photomasks, consist of a substrate, typically quartz, with the design or photomask pattern formed in molybdenum silicide (MoSi), chromium (Cr), or some other light absorber or blocker. Light is imaged through the photomask and onto the photosensitive coating on a semiconductor wafer. This pattern transfer can occur more than fifty times, using unique photomasks each time, during the course of manufacturing a semiconductor device.

As semiconductor devices have decreased in size, the photomask patterns used to make such devices have also decreased in size. As these photomask patterns decrease in size, they become more susceptible to defects that can ruin a portion of the photomask during manufacture. A defect is an unwanted localized feature that prevents accurate imaging of the design pattern onto the semiconductor wafer. For example, a defect may be an unwanted bridge between adjacent opaque features caused by a foreign particle contacting the photomask and masking the processing that should have generated a clear region.

Another source of defects is webbed images caused by marginal mask processes. Another kind of patterning problem is created when last-minute changes to the photomask design are requested. In this case, the photomask which was fabricated as originally intended, requires modification after the photomask pattern has been formed on the photomask. Accordingly, there is a need to repair or change the photomask's pattern after fabrication to include last-minute design changes to the photomask.

A traditional method of repairing photomasks after fabrication uses a laser beam to burn or ablate away the defective or otherwise unwanted portion of the photomask in order to remove that defective portion of the photomask pattern from the underlying glass substrate. In practice, a laser beam repair tool could focus a high energy laser beam onto the defective portion of the photomask to remove the unwanted pattern material, for example, chromium (Cr) or molybdenum silicide (MoSi). The spatial resolution of such laser systems restricts use of laser repair techniques on photomasks having small features. Accordingly, laser ablation photomask repair methods are restricted to photomasks with only larger features or to photomasks having defects spatially removed from small features.

Another traditional method of repairing a photomask pattern uses a focused ion beam (FIB). A FIB repair beam typically consists of gallium ions which can be focused and directed onto defective portions of the photomask to remove that portion of the photomask. FIB repair techniques have the advantage of high resolution, but may damage the substrate upon which the photomask pattern is created.

An alternate method of repairing photomasks uses an electron-beam (e-beam) instead of the ion beam to repair mask features. An electron beam is focused on the area to be repaired. In some instances, the energy from the electron beam provides enough energy to ablate the defect. More commonly a reactive gas is introduced into the chamber and the e-beam provides the activation energy for the gas to react only with the defect to form a volatile species that is subsequently removed. Since the reaction only occurs where the e-beam is present, very selective defect etching can occur. The reacting gas is very specific to the particular material to be removed. E-beam repair techniques have the advantage of excellent resolution and superior imaging but may damage the substrate or surrounding portions of the photomask.

There are various forms of substrate damage that can result from these three repair technologies. Damage may take the form of roughening the polished quartz substrate, thereby introducing unwanted opacity into a region of the photomask. Another form of substrate damage is the excessive removal of the quartz, called “river-bedding,” around the defective site. This creates a trench which can distort the imaged light. If the defect is removed by ablation or evaporation, splatter can occur in the vicinity of the removed defect. This redeposited splatter can attenuate light in an area of the photomask that is designed to be transparent.

A third problem, typical of traditional FIB defect repair processes is the gallium staining that occurs when a portion of the gallium ion beam is implanted into the glass substrate. This staining can occur during imaging and/or during the repair itself. The implanted gallium ions change the optical properties of the glass substrate and can cause phase and light transmission changes that can cause imaging problems during wafer exposure, resulting in printed defects on wafers. The gallium stain can be reduced by immersing the mask in a hydrofluoric (HF) etch bath to remove the stain. However, a hydrofluoric etch bath capable of removing the stain also etches the entire glass substrate resulting in a roughened surface across the mask.

The above described problems are just examples and there are various other problems with the currently available repair options for opaque photomask repairs. Accordingly, there is a need for a photomask repair method which allows repair photomasks while reducing damage to the area surrounding the defect being repaired.

### SUMMARY OF THE INVENTION

In a first aspect of the invention, a method for repairing a photomask includes depositing a masking film on a photomask, and removing a portion of the masking film corresponding to a defect in the photomask in a single processing step. The method also includes etching the defect in the photomask with an etchant.

In another aspect of the invention, a method for repairing a photomask includes covering a non-defective and defective portion of a photomask with a masking film, exposing the defective portion of the photomask by using a single step removal process, and etching away the defect.

In another aspect of the invention, a method of repairing opaque defects in a patterned mask includes applying an oxide layer to a surface of a patterned mask, and etching the oxide layer in the area of a defect with a focused energy beam. The method also includes etching away the defect with an etchant, and etching away the oxide layer with an etchant.

### BRIEF DESCRIPTION OF THE DRAWINGS

FIG. 1 is an illustration of a photomask repair method in accordance with the invention;

FIG. 2 is an illustration of a photomask repair method in accordance with the invention; and

FIG. 3 is a flow chart showing the logic flow of a repair method of a defect in a photomask in accordance with the invention.

### DETAILED DESCRIPTION OF EMBODIMENTS OF THE INVENTION

The invention is directed to, for example, removing a photomask pattern defect using an etching process where the region to be etched is defined by an opening in a masking film made by a focused energy beam, such as, for example, a FIB tool. The photomask pattern may also be referred to as a patterned opaque absorber. It will be understood that the term “opaque” applies to films that block all or substantially all light and may also be used to indicate films that transmit a certain portion of the incident light. The defect may be an unwanted opaque region in the photomask, and the defect may also be referred to as an opaque defect. A protective layer of material is applied over the patterned mask absorber film. An opening is formed in the film over the defect to expose the etchant by cutting a hole in a masking film. Accordingly, the invention combines the benefits of the spatial resolution of, for example, a laser, FIB, or e-beam repair system with the selectivity of the repair system and blanket RIE etch process to completely remove opaque material, while removing neither the protective mask layer, nor the underlying quartz substrate.

In addition, the invention reduces or eliminates the phase and transmission errors from quartz surface damage and gallium staining, which is increasingly important at smaller mask sizes and shorter wafer exposure wavelengths, e.g., 193 nm steppers. Additionally, embodiments of the invention include a conductive film on the masking film or hard mask to reduce ion beam deflection during the FIB or e-beam repair step by reducing charge build up.

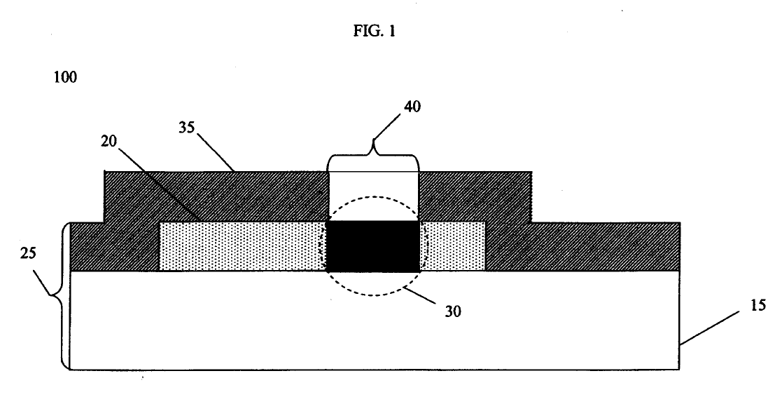

Referring to FIG. 1, an embodiment of repairing a defect in a photomask in accordance with the invention is shown. The transparent substrate 15 has an absorbing pattern 20 arranged thereon. Together, the transparent substrate 15 and the absorbing pattern 20 form a photomask 25. The transparent substrate 15 may be any transparent material suitable for forming a photomask thereon. For example, the transparent substrate may be made from quartz. The top surface and the bottom surface of the transparent substrate 15 may be polished to improve light transmission through the transparent substrate 15.

The absorbing pattern 20 is typically formed from an absorbing material such as chromium (Cr) or molybdenum silicide (MoSi). Together, the transparent substrate 15 and the absorbing pattern 20 form the photomask 25. It should be noted that embodiments of the invention will work with virtually all types of masks, such as, for example, chrome on glass mask (COG), attenuated phase shift masks, and alternating phase shift masks.

FIG. 1 also shows a defect 30. The defect 30 is formed in a region where there should be no absorbing pattern 20 material. By having such a defect 30, light will be blocked, attenuated, or otherwise distorted during wafer imaging. This will negatively affect the transfer of the pattern of the absorbing pattern 20 onto the wafer.

To remove the defect 30, a hard mask or masking film 35 is arranged over the absorbing pattern 20. The masking film 35 is a material which will be resistant to a subsequent etching process selected to remove the exposed defect 30, but not the masking film 35. The thickness of the masking film 35 is dependent on the choice of masking film 35 material, but could be about 300 nm thick if the masking film 35 is, for example, photoresist. Once the masking film 35 has been formed, an opening 40 is created in the masking film 35 which corresponds to the defect 30 of the absorbing pattern 20, i.e., the opening 40 is substantially directly above and follows the outline of the underlying defect 30.

The opening 40 in the masking film 35 is created with a repair or single processing step capable of selectively removing the portion of the masking film 35 whose location substantially corresponds to the location of the defect 30, thus creating the opening 40 above the defect 30 without affecting portions of the absorbing pattern 20 which are to remain. It should also be noted that if the defect 30 is a last-minute design change to the absorbing pattern 20, the repair tool is also able to remove those portions of the masking film 35 that correspond to the unwanted regions of the absorbing pattern 20.

The repair or single processing step generally uses a focused energy beam including a charged particle beam or an electromagnetic radiation beam. Examples of charged particle beams include a focused ion beam (FIB) and focused e-beams (FEB). Examples of electromagnetic beams include laser beams, x-rays and radio frequency waves. Other examples of focused energy beams include non-charged particle beams and acoustic energy beams. Where the focused energy beam is a FIB, it may be generally referred to as a FIB tool.

Though any type of focused energy beam suitable for selectively removing a portion of the mask material corresponding to the defect may be used, a FIB or alternatively an e-beam will used as an example of a single processing step removal method. For example, in one application, the masking film 35 is an oxide and the energy level of an ion beam used to remove the oxide is about 30 keV. Additionally, the masking film 35 could also be opened over the defect 30 by other methods, for example lithographic exposure to light with a subsequent develop or mechanical removal.

Once the opening 40 has been created in the masking film 35, the underlying defect 30 is exposed to an etchant. The etchant is chosen to selectively etch the material forming the absorbing pattern 20 without damaging the transparent substrate 15. The etching process may be a wet or dry etch, localized or across the entire photomask 25. The etchant may also be chosen so that the masking film 35 will protect the underlying absorbing pattern 20. Thus, the etchant is constrained to interact with only the defect 30. Accordingly, the etchant will remove only the defect 30 and thus repair the absorbing pattern 20 without causing harm to the underlying transparent substrate 15.

Once the defect 30 has been removed, the masking film 35 may be removed to restore the photomask structure to its original configuration without the defect 30. This final removal applies additional constraints to the masking film 35 choice since it must be removed without damaging the underlying absorbing pattern 20 and transparent substrate 15. If the masking film 35 is photoresist, a wet strip process using a sulfuric peroxide mixture can be used.

Since the FIB tool can be used to remove portions of the masking film 35, and the masking film 35 is not used for any optical processing, any gallium staining caused by the FIB tool to the masking layer 35 will have no effect on subsequent use of the photomask 25 during wafer exposures. Additionally, because the defect 30 is removed with the masking layer 35 in place, any damage or gallium staining is confined to the sacrificial masking film 35 and does not adversely affect the photomask structure 25.

In one embodiment of the invention, the masking layer 35 is, for example, a 100 nm layer of copper. The masking layer 35 could be other types of suitable metal of appropriate thickness. The copper is also stripped by a wet sulfuric peroxide mixture. Accordingly, there are many other possible combinations of masking materials and strips that could be used.

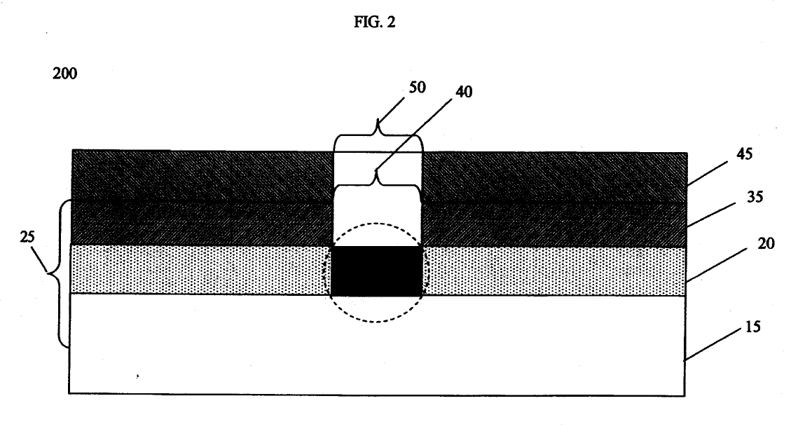

Referring to FIG. 2, a second embodiment of repairing a photomask is shown. Similar to FIG. 1, a photomask structure 25 includes a transparent substrate 15 and a photomask or absorbing pattern 20. Also similar to FIG. 1, a masking layer 35 is formed over the absorbing pattern 20. After the masking layer 35 is formed, a conductive layer 45 is formed on the masking layer 35. The conductive layer 45 may be formed from any suitable material which will conduct any charge deposited by a subsequent FIB or e-beam single step process. Thus, the conductive layer may be formed from a metal such as copper, aluminum, or tantalum or other conductive compounds such as molybdenum silicide or tantalum nitride. Additionally, the conductive layer 45 is formed to be about 10 nm to 100 nm in thickness

In use, a repair tool is used to remove and form an open portion 50 of the conductive layer 45 which corresponds to an underlying defect 30 in the absorbing pattern 20. Because the conductive layer 45 is conductive, any charge which builds up during the repair process while forming the open portion 50 may dissipate through the conductive layer 45, thereby allowing the ion or electron beam to be accurately targeted over the defect 30. Once the open portion 50 in the conductive layer 45 is formed, an opening 40 is formed in the masking layer 35 in a manner similar to that of FIG. 1. After openings, 40 and 50 are formed in the masking film 35 and conductive layer 45, respectively, an etchant is used to remove the defect 30 in the absorbing pattern 20 in a manner similar to that of FIG. 1.

Once the defect 30 has been removed, the conductive layer 45 is removed by any of the processes appropriate for removing such material without damaging the absorbing pattern 20 or the transparent substrate 15. Additionally, the masking film 35 is removed in a manner similar to that of FIG. 1.

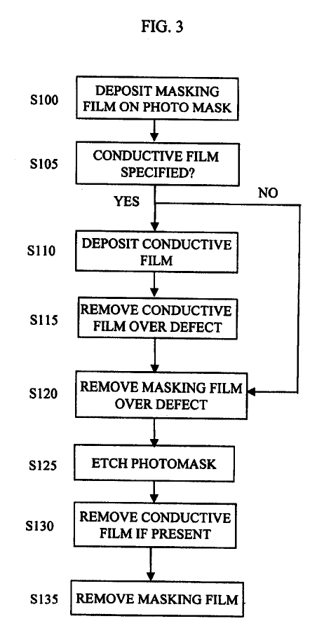

FIG. 3 is a flow diagram of an embodiment showing steps of using the invention. FIG. 3 may equally represent a high-level block diagram of components of the invention implementing the steps thereof. Continuing with the logic flow of FIG. 3, a masking film is deposited on an absorbing pattern of a photomask structure (S100). As described before, the masking film may be made of an oxide. Additionally, the absorbing pattern may be made of a metal or molybdenum silicide.

Next, it is determined whether a conductive film is to be deposited on the masking film (S105). If yes, the conductive film is deposited on the masking film (S110). The conductive film may be any suitable conductive material which will dissipate charge which may be built up during a focused energy beam removal process. After the conductive film is deposited, a portion of the conductive film corresponding to a defect in the underlying absorbing pattern is removed (S115). This portion of the conductive film is removed using a repair process which is well-known in the art.

If no conductive film is specified, or a portion corresponding to an underlying defect has been removed from the conductive film (S115), a portion of the masking film corresponding to a defect in the underlying photomask is removed (S120). The portion of the masking film is removed using a repair tool process well known in the art, which typically uses a focused gallium ion or an electron beam and provides high spatial resolution. After the portion of the masking film corresponding to the defect is removed, the exposed defect in the absorbing pattern is removed using a chemical etch (S125). The chemical etch is of a material suitable for selectively removing the material of the exposed defect while not harming the underlying transparent substrate.

It should be noted that the area to be etched is defined by the focused energy beam repair tool, while the actual removal of the defect is performed by the chemical etching process. The chemical etching process can be a wet etch, plasma etch, or other well known material removal process. Accordingly, the spatial resolution advantages of the focused energy beam repair tool are maintained while avoiding the potentially negative effects of damaging the transparent substrate or surrounding absorbing pattern with the repair tool processes.

When a conductive film is deposited, it is removed after defect removal (S130). The defect and conductive film are removed with a suitable etchant which will remove the respective materials without harming the absorbing pattern or transparent substrate. Finally, the masking film is removed (S135).

Accordingly, embodiments of the invention combine the benefits of the spatial resolution capabilities of a focused energy beam, such as, for example, a FIB or an e-beam repair system with the defect removal of the absorbing pattern etch process to achieve non-destructive, advanced mask repairs. Additionally, embodiments of the invention reduce or eliminate imaging phase error caused by damage to the transparent substrate and transmission errors from gallium staining, which is increasingly important at smaller photomask geometries and shorter wafer manufacturing exposure wavelengths.

In other words, a layer of oxide is introduced on top of an absorbing pattern. The small area of the oxide over the defect is removed to create a hard mask for each defect to be removed. The entire mask is then exposed to an etchant, however only the defect material is removed. Finally, the entire hard mask is removed. Embodiments of the invention incorporate an oxide layer and may also include a conductive film placed over a photomask during a mask repair process, after the mask has been patterned and inspected for defects. The layers are then locally removed with a focused energy beam repair system in the area of the defect, and the defect is then removed in an etching process. Subsequently, the layers are removed from the mask to leave the repaired photomask structure.

While the invention has been described in terms of exemplary embodiments, those skilled in the art will recognize that the invention can be practiced with modifications and in the spirit and scope of the appended claims. For instance, an e-beam, laser beam, or other suitable focused energy beam repair tool could be used instead of the FIB repair tool.

What is claimed is:

1. A method for repairing a photomask, comprising the steps of:
depositing a masking film on a photomask;
removing a portion of the masking film corresponding to a defect in the photomask in a single processing step; and
etching the defect in the photomask with an etchant.

2. The method of claim 1, further comprising removing the masking film after etching the defect.

3. The method of claim 1, wherein the single processing step includes removing a portion of the masking film corresponding to a defect in the photomask with a focused energy beam.

4. The method of claim 1, further comprising protecting a non-defective portion of the photomask from the etchant with the masking film.

5. The method of claim 1, further comprising forming the masking film from an oxide film and forming a photomask pattern of the photomask from a light blocking film.

6. The method of claim 1, further comprising arranging a conductive film over the masking film.

7. The method of claim 1 wherein the single processing step comprising removing a portion of the conductive film corresponding to a defect in the photomask pattern with a beam comprised of ions, electrons, and/or radiation.

8. A method for repairing a photomask, comprising the steps of covering a non-defective and defective portion of a photomask with a masking film, exposing the defective portion of the photomask by using a single step removal process and etching away the defective portion.

9. The method of claim 8, wherein covering a non-defective portion of a photomask with a masking film comprising removing a portion of the conductive film corresponding to a defect in the photomask pattern with a beam comprised of ions, electrons, and/or radiation.

10. The method of claim 8, further comprising removing the defective portion with an etchant.

11. The method of claim 8, wherein covering the non-defective portion of the photomask with the masking film comprises covering the non-defective portion of the photomask with an oxide film.

12. The method of claim 8, further comprising covering the non-defective portion of a photomask with a conductive film.

13. The method of claim 12, wherein covering the non-defective portion of a photomask with a conductive film comprises covering the masking film with a conductive film and removing a portion of the conductive film corresponding to the defective portion of the photomask.

14. The method of claim 8, further comprising forming the photomask pattern from a light blocking film.

15. A method of repairing opaque defects in a photomask pattern, comprising the steps of:
applying an oxide layer to a surface of a photomask pattern;
etching the oxide layer in the area of a defect with a focused energy beam;
etching away the defect with an etchant; and
etching away the oxide layer with an etchant.

16. The method of claim 15, wherein the oxide layer forms a hard mask.

17. The method of claim 16, wherein the hard mask is configured to shield a non-defective portion of the photomask pattern from an etchant.

18. The method of claim 15, further comprising arranging a conductive film over the oxide layer.

19. The method of claim 18, further comprising removing a portion of the conductive film corresponding to a defect in the photomask pattern with a beam comprised of ions, electrons, and/or radiation.

20. The method of claim 15, further comprising forming the photomask pattern from a light blocking film.
